(19) United States
(12) Patent Application Publication
(10) Pub. No.: US 2024/0287354 A1
(43) Pub. Date: Aug. 29, 2024

(54) ADHESIVE SHEET FOR SEMICONDUCTOR ELEMENT FABRICATION

(71) Applicant: NITTO DENKO CORPORATION, Ibaraki-shi, Osaka (JP)

(72) Inventors: Jun AKIYAMA, Ibaraki-shi,Osaka (JP); Keita YOSHIDA, Ibaraki-shi, Osaka (JP)

(21) Appl. No.: 18/572,140

(22) PCT Filed: Feb. 22, 2022
(86) PCT No.: PCT/JP2022/007278

§ 371 Date: Dec. 19, 2023

(30) Foreign Application Priority Data
Jun. 21, 2021 (JP) 2021-102655

(51) Int. Cl. C09J 7/38

(52) U.S. Cl. CPC C09J 7/38; C09J 2203/326; C09J 2301/312

(57) ABSTRACT

Provided is a pressure-sensitive adhesive sheet for processing a semiconductor element, which is capable of protecting a semiconductor element from electrostatic breakdown caused by peeling electrification and frictional electrification even under a high-humidity environment and/or under the application of a high voltage. The pressure-sensitive adhesive sheet includes a pressure-sensitive adhesive layer and a base material. A surface resistivity ρs_{BM} of the base material and a surface resistivity ρs_{PA} of the pressure-sensitive adhesive layer are each 1.0×10¹³Ω/□ or less. In one embodiment, a surface resistivity ρs_{10VBM} of the base material at a time of application of 10 V and a surface resistivity ρs_{10VPA} of the pressure-sensitive adhesive layer at a time of application of 10 V, and a surface resistivity ρs_{1000VBM} 1,000 V and a surface resistivity ρs_{1000VPA} 1,000 V satisfy the following expression (1) and expression (2).

$${ρs}_{1000 VBM} / {ρs}_{10 VBM} \leq 1 , 000 \qquad ( 1 )$$

$${ρs}_{1000 VPA} / {ρs}_{10 VPA} \leq 1 , 000 \qquad ( 2 )$$

### TECHNICAL FIELD

The present invention relates to a pressure-sensitive adhesive sheet for processing a semiconductor element.

### BACKGROUND ART

A semiconductor element is produced by subjecting a silicon wafer to a backgrinding process and a dicing process. In those processes, a pressure-sensitive adhesive sheet for processing a semiconductor element is used in order to support and protect the silicon wafer. In a manufacturing process for the semiconductor element, the silicon wafer and the pressure-sensitive adhesive sheet may be charged due to various factors. For example, there are given peeling electrification when the pressure-sensitive adhesive sheet is peeled from a chuck table after the dicing process, peeling electrification when the semiconductor element is picked up, and frictional electrification caused by scratching for collecting the wafer cut into small pieces from the pressure-sensitive adhesive sheet. Due to peeling electrification and frictional those electrification, the semiconductor element is electrostatically broken, and the yield thereof may be decreased.

It has been known that antistatic performance is imparted to a pressure-sensitive adhesive sheet to be used in a semiconductor-processing process with an antistatic agent (e.g., Patent Literature 1 and Patent Literature 2). The voltage generated by peeling electrification and frictional electrification is hundreds of volts or more, which not only electrostatically breaks the semiconductor element but may also deteriorate the antistatic performance of the pressure-sensitive adhesive sheet. In addition, the antistatic performance of the pressure-sensitive adhesive sheet may be deteriorated during transportation and storage. In particular, the deterioration of antistatic performance may become conspicuous under high-temperature and high-humidity conditions, such as in a tropical region. Thus, appropriate antistatic performance may not be exhibited in a situation in which antistatic performance is required.

### CITATION LIST

### Patent Literature

[PTL 1] JP 2020-174201 A
[PTL 2] WO 2018/003893 A1

### SUMMARY OF INVENTION

### Technical Problem

The present invention has been made to solve the problems of the related art, and an object of the present invention is to provide a pressure-sensitive adhesive sheet for processing a semiconductor element, which is capable of protecting a semiconductor element from electrostatic breakdown caused by peeling electrification and frictional electrification even under a high-humidity environment and/or under the application of a high voltage.

### Solution to Problem

According to an embodiment of the present invention, there is provided a pressure-sensitive adhesive sheet for processing a semiconductor element, including: a base material; and a pressure-sensitive adhesive layer, wherein a surface resistivity ρs_{BM} of the base material and a surface resistivity ρs_{PA} of the pressure-sensitive adhesive layer are each 1.0×10¹³Ω/□ or less, and wherein a surface resistivity ρs_{10VBM} of the base material at a time of application of 10 V and a surface resistivity ρs_{10VPA} of the pressure-sensitive adhesive layer at a time of application of 10 V, and a surface resistivity ρs_{1000VBM} of the base material at a time of application of 1,000 V and a surface resistivity ρs_{1000VPA} of the pressure-sensitive adhesive layer at a time of application of 1,000 V satisfy the following expression (1) and expression (2).

$${ρs}_{1000 VBM} / {ρs}_{10 VBM} \leq 1 , 000 \qquad ( 1 )$$

$${ρs}_{1000 VPA} / {ρs}_{10 VPA} \leq 1 , 000 \qquad ( 2 )$$

According to another embodiment of the present invention, there is provided a pressure-sensitive adhesive sheet for processing a semiconductor element, including: a base material; and a pressure-sensitive adhesive layer, wherein a surface resistivity ρs_{BM} of the base material and a surface resistivity ρs_{PA} of the pressure-sensitive adhesive layer are each 1.0×10¹³Ω/□ or less, and wherein a surface resistivity ρs_{92% BM} of the base material at a humidity of 92% and a surface resistivity ρs_{92% PA} of the pressure-sensitive adhesive layer at a humidity of 92% satisfy the following expression (3) and expression (4).

$${ρs}_{92 \% BM} / {ρs}_{BM} \leq 1 , 000 \qquad ( 3 )$$

$${ρs}_{92 \% PA} / {ρs}_{PA} \leq 1 , 000 \qquad ( 4 )$$

In one embodiment, the pressure-sensitive adhesive layer contains an ionic liquid.

In one embodiment, a content of the ionic liquid in a composition for forming the pressure-sensitive adhesive layer is from 0.1 wt % to 50 wt %.

In one embodiment, the base material has an antistatic layer on at least one surface thereof, and the antistatic layer contains a quaternary ammonium salt.

In one embodiment, a content of the quaternary ammonium salt in a composition for forming the antistatic layer is from 0.1 wt % to 50 wt %.

### Advantageous Effects of Invention

With the pressure-sensitive adhesive sheet for processing a semiconductor element according to the embodiment of the present invention, a semiconductor element can be protected from electrostatic breakdown caused by peeling electrification and frictional electrification even under a high-humidity environment and/or under the application of a high voltage. In the pressure-sensitive adhesive sheet for processing a semiconductor element according to the embodiment of the present invention, deterioration of antistatic performance can be prevented even under a high-humidity condition and under the application of a high voltage. Thus, through use of the pressure-sensitive adhesive sheet for processing a semiconductor element according to the embodiment of the present invention, the semiconductor element can be manufactured with a high yield.

### BRIEF DESCRIPTION OF DRAWINGS

FIG. 1 is a schematic sectional view of a pressure-sensitive adhesive sheet for processing a semiconductor element according to an embodiment of the present invention.

### DESCRIPTION OF EMBODIMENTS

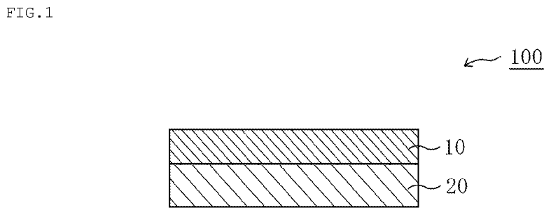

A. Overall Configuration of Pressure-sensitive Adhesive Sheet for processing Semiconductor Element FIG. 1 is a schematic sectional view of a pressure-sensitive adhesive sheet for processing a semiconductor element (hereinafter also referred to as “pressure-sensitive adhesive sheet for processing”) according to an embodiment of the present invention. A pressure-sensitive adhesive sheet 100 for processing a semiconductor element includes a base material 10 and a pressure-sensitive adhesive layer 20 arranged on one surface of the base material. In one embodiment, the base material 10 has an antistatic layer (not shown) on at least one surface thereof. The antistatic layer may be formed on a surface of the base material 10 on the pressure-sensitive adhesive layer 20 side, a surface of the base material 10 which is not in contact with the pressure-sensitive adhesive layer 20, or both sides thereof. The antistatic layer is preferably formed at least on the surface of the base material 10 which is not in contact with the pressure-sensitive adhesive layer 20. The pressure-sensitive adhesive sheet for processing a semiconductor element according to the embodiment of the present invention may include any appropriate other layer (not shown). For example, any appropriate layer may be formed between the base material and the pressure-sensitive adhesive layer. A separator may be arranged outside the pressure-sensitive adhesive layer for the purpose of protecting the pressure-sensitive adhesive layer until the pressure-sensitive adhesive sheet for processing a semiconductor element is brought into use.

In the pressure-sensitive adhesive sheet for processing a semiconductor element according to the embodiment of the present invention, a surface resistivity ρs_{BM} of the base material and a surface resistivity ρs_{PA} of the pressure-sensitive adhesive layer are each 1.0×10¹³Ω/□ or less. When the ρs_{BM} and the ρs_{PA} are each 1.0×10¹³Ω/□ or less, a semiconductor element can be protected from electrostatic breakdown caused by peeling electrification and frictional electrification. As used herein, the surface resistivities ρs_{BM} and SPA each refer to a surface resistivity measured in conformity with JIS K 6911.

In one embodiment, in the pressure-sensitive adhesive sheet for processing a semiconductor element according to the embodiment of the present invention, a surface resistivity ρs_{10VBM} of the base material at the time of application of 10 V and a surface resistivity ρs_{10VPA} of the pressure-sensitive adhesive layer at the time of application of 10 V, and a surface resistivity ρs_{1000VBM} of the base material at the time of application of 1,000 V and a surface resistivity ρs_{1000VPA} of the pressure-sensitive adhesive layer at the time of application of 1,000 V satisfy the following expression (1) and expression (2). When the surface resistivities ρs_{10VBM}, ρs_{10VPA}, ρs_{1000VBM}, and ρs_{1000VPA} satisfy the expression (1) and the expression (2), a semiconductor element can be appropriately protected from peeling electrification and frictional electrification even under the application of a high voltage.

$${ρs}_{1000 VBM} / {ρs}_{10 VBM} \leq 1 , 000 \qquad ( 1 )$$

$${ρs}_{1000 VPA} / {ρs}_{10 VPA} \leq 1 , 000 \qquad ( 2 )$$

The ρs_{1000VBM}/ρs_{10VBM} and the ρs_{1000VPA}/ρs_{10VPA} are each preferably 100 or less, more preferably 10 or less, still more preferably 1 or less. That is, the surface resistivity can be maintained even under the application of a high voltage. As used herein, the surface resistivities ρs_{10VBM} and ρs_{10VPA} at the time of application of 10 V each refer to a surface resistivity measured in conformity with JIS K 6911 after the pressure-sensitive adhesive sheet for processing a semiconductor element is placed under the conditions of an application voltage of 10 V for 1 minute. In addition, the surface resistivities ρs_{1000VBM} and ρs_{1000VPA} at the time of application of 1,000 V each refer to a surface resistivity measured in conformity with JIS K 6911 after the pressure-sensitive adhesive sheet for processing a semiconductor element is placed under the conditions of an application voltage of 1,000 V for 1 minute.

In one embodiment, in the pressure-sensitive adhesive sheet for processing a semiconductor element according to the embodiment of the present invention, a surface resistivity ρs_{92% BM} of the base material at a humidity of 92% and a surface resistivity ρs_{92% PA} of the pressure-sensitive adhesive layer at a humidity of 92% satisfy the following expression (3) and expression (4). When the surface resistivities ρs_{92% BM} and ρs_{92% PA} at a humidity of 92% satisfy the expression (3) and the expression (4), a semiconductor element can be appropriately protected from peeling electrification and frictional electrification even under a high-humidity condition.

$${ρs}_{92 \% BM} / {ρs}_{BM} \leq 1 , 000 \qquad ( 3 )$$

$${ρs}_{92 \% PA} / {ρs}_{PA} \leq 1 , 000 \qquad ( 4 )$$

The ρs_{92% BM}/ρs_{BM} and the ρs_{92% PA}/ρs_{PA} are each preferably 100 or less, more preferably 10 or less, still more preferably 1 or less. That is, the surface resistivity can be maintained even after the pressure-sensitive adhesive sheet for processing a semiconductor element is placed under a high-humidity environment (e.g., humidity of 92%). As used herein, the surface resistivities ρs_{92% BM} and ρs_{92% PA} at a humidity of 92% each refer to a surface resistivity measured in conformity with JIS K 6911 after the pressure-sensitive adhesive sheet for processing a semiconductor element is left to stand still for 3 days under the conditions of 40° C. and 92% RH.

The thickness of the pressure-sensitive adhesive sheet for processing a semiconductor element according to the embodiment of the present invention may be set to any appropriate thickness. For example, the thickness of the pressure-sensitive adhesive sheet for processing a semiconductor element is preferably from 15 μm to 500 μm, more preferably from 50 μm to 400 μm, still more preferably from 80 μm to 200 μm. When the thickness falls within the above-mentioned ranges, the sheet can appropriately support a semiconductor element, and hence its handleability can be maintained. In addition, the conveyance of the element with an apparatus can be efficiently performed, and hence a reduction in yield can be prevented.

### B. Base Material

Any appropriate base material is used as the base material 10. The base material may be a single layer, or may be a laminate of two or more layers. When the base material is a laminate of two or more layers, the layers are used so that the total thickness of the base material may be the thickness of the base material to be described later.

The thickness of the base material is preferably from 10 μm to 500 μm, more preferably from 30 μm to 300 μm, still more preferably from 50 μm to 300 μm. When the thickness of the base material falls within the above-mentioned ranges, the sheet can appropriately support a semiconductor element, and hence the occurrence of its warping and/or deflection can be prevented.

The surface resistivity ρs_{BM} of the base material is preferably from 1.0×10⁵Ω/□ to 1.0×10¹³Ω/□, more preferably from 1.0×10⁷Ω/□ to 1.0×10¹²Ω/□. When the surface resistivity ρs_{BM} of the base material falls within the above-mentioned ranges, a semiconductor element can be appropriately protected from peeling electrification and frictional electrification even under the application of a high voltage from outside.

The base material may be formed of any appropriate resin. Specific examples of the resin for forming the base material include polyester-based resins, such as polyethylene naphthalate (PEN), polybutylene terephthalate (PBT), and polybutylene naphthalate (PBN), polyolefin-based resins, such as an ethylene-vinyl acetate copolymer, an ethylene-methyl methacrylate copolymer, polyethylene, polypropylene, and an ethylene-propylene copolymer, polyvinyl alcohol, polyvinylidene chloride, polyvinyl chloride, a vinyl chloride-vinyl acetate copolymer, polyvinyl acetate, polyamide, polyimide, celluloses, a fluorine-based resin, polyether, polystyrene-based resins such as polystyrene, polycarbonate, polyether sulfone, and polyetheretherketone. Of those, polyolefin-based resins, such as an ethylene-vinyl acetate copolymer, polyethylene, polypropylene, and an ethylene-propylene copolymer, are preferably used.

The base material may further include another component to the extent that the effects of the present invention are not inhibited. Examples of the other component include an antioxidant, a UV absorber, a light stabilizer, and an antistatic agent. With regard to the kind and usage amount of the other component, the other component may be used in any appropriate amount in accordance with purposes.

The pressure-sensitive adhesive sheet for processing a semiconductor element according to the embodiment of the present invention preferably has an antistatic layer on at least one surface of the base material. When the base material has the antistatic layer, the pressure-sensitive adhesive sheet for processing a semiconductor element, which satisfies the above-mentioned expression (1) and expression (2) or the above-mentioned expression (3) and expression (4), can be more easily obtained. The pressure-sensitive adhesive sheet for processing a semiconductor element according to the embodiment of the present invention more preferably has the antistatic layer at least on the surface of the base material which is not in contact with the pressure-sensitive adhesive layer. When the base material has the antistatic layer on the surface that is not in contact with the pressure-sensitive adhesive layer, a semiconductor element can be protected even under the application of a high voltage from outside. When the base material has the antistatic layer, the surface resistivity of the base material as used herein may refer to the surface resistivity of the surface of the base material on which the antistatic layer is formed.

The antistatic layer preferably contains a quaternary ammonium salt. The quaternary ammonium salt may function as an antistatic agent. When the antistatic layer contains the quaternary ammonium salt, a semiconductor element can be protected from electrostatic breakdown caused by peeling electrification and frictional electrification even under a high-humidity environment and/or under the application of a high voltage. The quaternary ammonium salts may be used alone or in combination thereof.

Any appropriate quaternary ammonium salt may be used as the quaternary ammonium salt. Examples thereof include salts of quaternary ammoniums, such as tetraethylammonium, tetramethylammonium, tetrapropylammonium, N, N, N-triethyl-N-(2-hydroxyethyl) ammonium, and N, N-diethyl-N, N-di (2-hydroxyethyl) ammonium, and quaternary ammonium hydroxide salts such as 2-hydroxyethyltrimethylammonium hydroxide (choline). Of those, 2-hydroxyethyltrimethylammonium hydroxide may be preferably used. When such quaternary ammonium salt is used, a semiconductor element can be further protected from electrostatic breakdown caused by peeling electrification and frictional electrification even under a high-humidity environment and/or under the application of a high voltage.

The antistatic layer may be formed by any appropriate method. For example, the antistatic layer may be formed by applying a composition for forming the antistatic layer containing the above-mentioned quaternary ammonium salt (antistatic layer-forming composition) onto the base material, followed by drying. Any appropriate solvent may be used as a solvent to be used in the antistatic layer-forming composition. Examples thereof include water and organic solvents including alcohols, such as methanol, ethanol, and isopropyl alcohol, and ketones, such as acetone, methyl ethyl ketone, ethyl acetate, toluene, and xylene.

In the antistatic layer-forming composition, the quaternary ammonium salt is used in any appropriate amount so that the surface resistivity ρs_{BM} of the base material (e.g., the surface of the base material on the antistatic layer side on which the antistatic layer is formed) becomes 1.0×10¹³Ω/□ or less. The content of the quaternary ammonium salt in the antistatic layer-forming composition is, for example, from 0.01 wt % to 50 wt %, preferably from 0.1 wt % to 30 wt %, more preferably from 1 wt % to 10 wt %. When the content of the quaternary ammonium salt falls within the above-mentioned ranges, a semiconductor element can be further protected from electrostatic breakdown caused by peeling electrification and frictional electrification even under a high-humidity environment and/or under the application of a high voltage.

The thickness of the antistatic layer may be set to any appropriate thickness. The thickness of the antistatic layer is, for example, from 50 nm to 5,000 nm, preferably from 70 nm to 1,000 nm, more preferably from 80 nm to 200 nm. When the thickness of the antistatic layer falls within the above-mentioned ranges, a semiconductor element can be protected from electrostatic breakdown caused by peeling electrification and frictional electrification even under a high-humidity environment and/or under the application of a high voltage.

### C. Pressure-Sensitive Adhesive Layer

The pressure-sensitive adhesive layer 20 is formed by using a composition containing any appropriate pressure-sensitive adhesive (hereinafter also referred to as “pressure-sensitive adhesive layer-forming composition”). The pressure-sensitive adhesive layer 20 preferably contains an ionic liquid. The ionic liquid may function as an antistatic agent. When the pressure-sensitive adhesive layer contains the ionic liquid, a semiconductor element can be protected from electrostatic breakdown caused by peeling electrification and frictional electrification even under a high-humidity environment and/or under the application of a high voltage.

The surface resistivity ρs_{PA} of the pressure-sensitive adhesive layer is preferably from 1.0×10⁵Ω/□ to 1.0×10¹³Ω/□, more preferably from 1.0×10⁸Ω/□ to 1.0×10¹²Ω/□. A semiconductor element can be appropriately protected from peeling electrification and frictional electrification even when the semiconductor element and the pressure-sensitive adhesive sheet for processing a semiconductor element are subjected to a process in which a high voltage is applied.

The thickness of the pressure-sensitive adhesive layer may be set to any appropriate value. The thickness of the pressure-sensitive adhesive layer is preferably from 1 μm to 100 μm, more preferably from 1 μm to 20 μm, still more preferably from 1 μm to 10 μm. When the thickness of the pressure-sensitive adhesive layer falls within the above-mentioned ranges, the layer can exhibit sufficient pressure-sensitive adhesive strength to an adherend.

### C-1. Pressure-sensitive Adhesive Composition

a. Any appropriate pressure-sensitive adhesive is used as the pressure-sensitive adhesive layer-forming composition (the pressure-sensitive adhesive). Examples thereof include an acrylic pressure-sensitive adhesive, a rubber-based pressure-sensitive adhesive, a silicone-based pressure-sensitive adhesive, and a polyvinyl ether-based pressure-sensitive adhesive.

In one embodiment, the pressure-sensitive adhesive layer-forming composition is preferably an active energy ray-curable pressure-sensitive adhesive composition. Through use of the active energy ray-curable pressure-sensitive adhesive composition, for example, the pressure-sensitive adhesive strength is decreased by irradiation with an active energy ray (typically, a UV-ray) after dicing, and it becomes easy to pick up a workpiece (e.g., a semiconductor chip) cut into small pieces, with the result that the peeling electrification at the time of pickup can be suppressed.

### C-1-1. Base Polymer

b. The pressure-sensitive adhesive composition may contain a base polymer showing a pressure-sensitive adhesive property. A monomer for forming the base polymer is, for example, a hydrophilic monomer. Any appropriate monomer having a polar group may be used as the hydrophilic monomer. Specific examples thereof include: carboxyl group-containing monomers, such as acrylic acid, methacrylic acid, carboxyethyl acrylate, carboxypentyl acrylate, itaconic acid, maleic acid, fumaric acid, and crotonic acid; acid anhydride monomers, such as maleic anhydride and itaconic anhydride; hydroxyl group-containing monomers, such as 2-hydroxyethyl (meth) acrylate, 2-hydroxypropyl (meth) acrylate, 4-hydroxybutyl (meth) acrylate, 6-hydroxyhexyl (meth) acrylate, 8-hydroxyoctyl (meth) acrylate, 10-hydroxydecyl (meth) acrylate, 12-hydroxylauryl (meth) acrylate, and (4-hydroxymethylcyclohexyl) methyl methacrylate; sulfonic acid group-containing monomers, such as styrenesulfonic acid, allylsulfonic acid, 2-(meth) acrylamido-2-methylpropanesulfonic acid, (meth) acrylamidopropanesulfonic acid, sulfopropyl (meth) acrylate, and (meth) acryloyloxynaphthalenesulfonic acid; phosphoric acid group-containing monomers such as 2-hydroxyethylacryloyl phosphate; (N-substituted) amide-based monomers, such as N, N-(meth) acrylamide, dimethyl (meth) acrylamide, N-butyl (meth) acrylamide, N-methylol (meth) acrylamide, N-methylolpropane (meth) acrylamide, and acryloylmorpholine; aminoalkyl (meth) acrylate-based monomers, such as aminoethyl (meth) acrylate, N, N-dimethylaminoethyl (meth) acrylate, and t-butylaminoethyl (meth) acrylate; alkoxyalkyl (meth) acrylate-based monomers, such as methoxyethyl (meth) acrylate and ethoxyethyl (meth) acrylate; maleimide-based monomers, such as N-cyclohexylmaleimide, N-isopropylmaleimide, N-laurylmaleimide, and N-phenylmaleimide; itaconimide-based monomers, such as N-methyl itaconimide, N-ethyl itaconimide, N-butyl itaconimide, N-octyl itaconimide, N-2-ethylhexyl itaconimide, N-cyclohexyl itaconimide, and N-lauryl itaconimide; succinimide-based monomers, such as N-(meth) acryloyloxymethylene succinimide, N-(meth) acryloyl-6-oxyhexamethylene succinimide, and N-(meth) acryloyl-8-oxyoctamethylene succinimide; vinyl-based monomers, such as vinyl acetate, vinyl propionate, N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, N-vinylcarboxylic acid amides, styrene, α-methylstyrene, and N-vinylcaprolactam; cyanoacrylate monomers, such as acrylonitrile and methacrylonitrile; epoxy group-containing acrylic monomers such as glycidyl (meth) acrylate; glycol-based acrylate monomers, such as polyethylene glycol (meth) acrylate, polypropylene glycol (meth) acrylate, methoxyethylene glycol (meth) acrylate, and methoxypolypropylene glycol (meth) acrylate; acrylate-based monomers each having, for example, a heterocycle, a halogen atom, or a silicon atom, such as tetrahydrofurfuryl (meth) acrylate, fluorine (meth) acrylate, and silicon (meth) acrylate; and polyfunctional monomers, such as hexanediol di (meth) acrylate, (poly) ethylene glycol di (meth) acrylate, (poly) propylene glycol di (meth) acrylate, neopentyl glycol di (meth) acrylate, pentaerythritol di (meth) acrylate, trimethylolpropane tri (meth) acrylate, pentaerythritol tri (meth) acrylate, dipentaerythritol hexa (meth) acrylate, epoxy acrylate, polyester acrylate, and urethane acrylate. Of those, hydroxyl group-containing monomers and/or (N-substituted) amide-based monomers may each be suitably used as the hydrophilic monomer. The hydrophilic monomers may be used alone or in combination thereof.

In addition, the hydrophilic monomer may be used in combination with a hydrophobic monomer. The hydrophobic monomer only needs to be a monomer having a hydrophobic property, and any appropriate monomer may be used. Specific examples thereof include: vinyl alkyl or aryl ethers each having an alkyl or aryl group having 9 to 30 carbon atoms, such as vinyl 2-ethylhexanoate, vinyl laurate, vinyl stearate, and stearyl vinyl ether; alkyl esters each having 6 to 30 carbon atoms, such as hexyl (meth) acrylate, heptyl (meth) acrylate, octyl (meth) acrylate, isooctyl acrylate, isononyl acrylate, decyl (meth) acrylate, isodecyl (meth) acrylate, dodecyl (meth) acrylate, 2-ethylhexyl (meth) acrylate, benzyl (meth) acrylate, lauryl (meth) acrylate, oleyl (meth) acrylate, palmityl (meth) acrylate, and stearyl (meth) acrylate; unsaturated vinyl esters of (meth) acrylic acid derived from a fatty acid and an aliphatic alcohol; a monomer derived from cholesterol; and olefin monomers, such as 1-butene, 2-butene, 1-pentene, 1-hexene, 1-octene, isobutylene, and isoprene. The hydrophobic monomers may be used alone or in combination thereof. The hydrophobic monomer to be used in the present invention refers to a monomer which has a solubility in 100 g of water of 0.02 g or less.

The base polymer may further contain a monomer component other than the hydrophilic monomer and the hydrophobic monomer. Examples of the other monomer component include alkyl acrylates, such as butyl acrylate and ethyl acrylate. The other monomer components may be used alone or in combination thereof.

The base polymer may further contain a constituent unit derived from an isocyanate-based compound having a curable functional group in a molecule thereof. The base polymer containing the constituent unit derived from the isocyanate-based compound may be obtained by, for example, causing a substituent that a constituent unit derived from the hydrophilic monomer has (e.g., a OH group) and the NCO group of the isocyanate-based compound to react with each other. Examples of the isocyanate-based compound include methacryloyl isocyanate, 2-methacryloyloxyethyl isocyanate, 2-acryloyloxyethyl isocyanate, and m-isopropenyl-α, α-dimethylbenzyl isocyanate.

The weight-average molecular weight of the base polymer for forming the pressure-sensitive adhesive is preferably from 300,000 to 2,000,000, more preferably from 500,000 to 1,500,000. The weight-average molecular weight may be measured by GPC (solvent: THE).

### C-1-2. Active Energy Ray-reactive Oligomer and Thermosetting Oligomer

c. The pressure-sensitive adhesive composition further contains preferably an active energy ray-reactive oligomer and/or a thermosetting oligomer, more preferably an active energy ray-reactive oligomer. The active energy ray-reactive oligomers and the thermosetting oligomers may be used alone or in combination thereof.

Examples of the active energy ray-reactive oligomer include a urethane acrylic oligomer, an epoxy (meth) acrylic oligomer, and an acryl (meth) acrylic oligomer. Of those, a urethane acrylic oligomer, an acryl (meth) acrylic oligomer, or the like is preferably used.

A commercially available product may be used as the active energy ray-reactive oligomer. Examples thereof include SHIKOH (trademark) UV-3000B (weight-average molecular weight: 18,000) manufactured by The Nippon Synthetic Chemical Industry Co., Ltd. and a product available under the product name “ARONIX M321” (weight-average molecular weight: 10,000) from Toagosei Co., Ltd.

For example, any appropriate oligomer having at least one thermosetting functional group, such as a glycidyl group, a carboxyl group, a hydroxyl group, or an amino group, may be used as the thermosetting oligomer.

The weight-average molecular weight of each of the active energy ray-reactive oligomer and the thermosetting oligomer is preferably 5,000 or more, more preferably 7,000 or more, still more preferably 8,000 or more, particularly preferably 10,000 or more. In addition, the weight-average molecular weight of each of the active energy ray-reactive oligomer and the thermosetting oligomer is preferably 70,000 or less, more preferably 50,000 or less. The weight-average molecular weight of each of the active energy ray-reactive oligomer and the thermosetting oligomer may be measured by, for example, GPC (solvent: THE).

### C-1-3. Polymerization Initiator

d. The pressure-sensitive adhesive layer-forming composition typically contains a polymerization initiator. Any appropriate initiator may be used as the polymerization initiator, and a photopolymerization initiator is preferably used. Any appropriate initiator may be used as the photopolymerization initiator. Examples of the photopolymerization: initiator include: α-ketol-based compounds, such as 4-(2-hydroxyethoxy) phenyl (2-hydroxy-2-propyl) ketone, α-hydroxy-α,α′-dimethylacetophenone, 2-methyl-2-hydroxypropiophenone, and 1-hydroxycyclohexyl phenyl ketone; acetophenone-based compounds, such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether-based compounds, such as benzoin ethyl ether, benzoin isopropyl ether, and anisoin methyl ether; ketal-based compounds such as benzyl dimethyl ketal; aromatic sulfonyl chloride-based compounds such as 2-naphthalenesulfonyl chloride; photoactive oxime-based compounds such as 1-phenone-1,1-propanedione-2-(0-ethoxycarbonyl) oxime; benzophenone-based compounds, such as benzophenone, benzoylbenzoic acid, and 3,3′-dimethyl-4-methoxybenzophenone; thioxanthone-based compounds, such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphinoxides; and acylphosphonates. The photopolymerization initiators may be used alone or in combination thereof. The usage amount of the photopolymerization initiator may be set to any appropriate amount. The usage amount of the photopolymerization initiator is preferably from 1 part by weight to 10 parts by weight, more preferably from 3 parts by weight to 7 parts by weight with respect to 100 parts by weight of the base polymer.

A commercially available product may be used as the photopolymerization initiator. Examples thereof include products available under the product names “IRGACURE 651”, “IRGACURE 184”, “IRGACURE 369”, “IRGACURE 819”, and “IRGACURE 2959” from BASF, and a product available under the product name “Omnirad 2959” from IGM Resins B.V.

### C-1-4. Cross-linking Agent

e. The pressure-sensitive adhesive layer-forming composition preferably further contains a cross-linking agent. Examples of the cross-linking agent include an isocyanate-based cross-linking agent, an epoxy-based cross-linking agent, an oxazoline-based cross-linking agent, an aziridine-based cross-linking agent, a melamine-based cross-linking agent, a peroxide-based cross-linking agent, a urea-based cross-linking agent, a metal alkoxide-based cross-linking agent, a metal chelate-based cross-linking agent, a metal salt-based cross-linking agent, a carbodiimide-based cross-linking agent, and an amine-based cross-linking agent.

In one embodiment, an isocyanate-based cross-linking agent is preferably used. The isocyanate-based cross-linking agent is preferred because the agent may react with many kinds of functional groups. Specific examples of the isocyanate-based cross-linking agent include: lower aliphatic polyisocyanates, such as butylene diisocyanate and hexamethylene diisocyanate; alicyclic isocyanates, such as cyclopentylene diisocyanate, cyclohexylene diisocyanate, and isophorone diisocyanate; aromatic isocyanates, such as 2,4-tolylene diisocyanate, 4,4′-diphenylmethane diisocyanate, and xylylene diisocyanate; and isocyanate adducts, such as a trimethylolpropane/tolylene diisocyanate trimer adduct (manufactured by Tosoh Corporation, product name: “Coronate L”), a trimethylolpropane/hexamethylene diisocyanate trimer adduct (manufactured by Nippon Polyurethane Industry Co., Ltd., product name: “Coronate HL”), and an isocyanurate body of hexamethylene diisocyanate (manufactured by Nippon Polyurethane Industry Co., Ltd., product name: “Coronate HX”). Of those, a cross-linking agent having 3 or more isocyanate groups is preferably used.

The active energy ray-curable pressure-sensitive adhesive composition may further contain any appropriate additive. Examples of the additive include an active energy ray polymerization accelerator, a radical scavenger, a tackifier, a plasticizer (e.g., a trimellitate-based plasticizer or a pyromellitate-based plasticizer), a pigment, a dye, a filler, an age resistor, a conductive material, an antistatic agent, a UV absorber, a light stabilizer, a peeling modifier, a softener, a surfactant, a flame retardant, and an antioxidant.

With regard to the content of the cross-linking agent, the cross-linking agent may be used in any appropriate amount. For example, the content of the cross-linking agent is preferably from 0.1 part by weight to 10 parts by weight, more preferably from 0.5 part by weight to 8 parts by weight with respect to 100 parts by weight of the base polymer. When the content falls within such ranges, a pressure-sensitive adhesive layer whose modulus of elasticity is appropriately adjusted can be formed.

### C-2. Ionic Liquid

f. Any appropriate ionic liquid may be used as the ionic liquid. The ionic liquid refers to a salt that is formed of a cation and an anion, and is a liquid at 25° C. The ionic liquids may be used alone or in combination thereof.

The cation of the ionic liquid is preferably a non-metallic ion, and examples thereof include an imidazolium-based cation, a pyridinium-based cation, a pyrrolidinium-based cation, a quaternary ammonium-based cation, and a quaternary phosphonium-based cation. Of those, an imidazolium cation may be preferably used. When such cation is used, a semiconductor element can be protected from electrostatic breakdown caused by peeling electrification and frictional electrification even under a high-humidity environment and/or under the application of a high voltage.

Examples of the anion of the ionic liquid include an anion represented by the following general formula (A), CF₃CO₂⁻, CF₃ (CF₂)₃SO₃⁻, CF₃SO₃⁻, (CF₃SO₂)₃C⁻, CF₃ (CF₂)₂CO₂⁻, BF₃(CF₃)⁻, BF₃(C₂F₅)⁻, BF₃(C₃F₇)⁻, BF₂(CF₃)₂⁻, BF₂(CF₃) (C₂F₅)⁻, PF₅(CF₃)⁻, PF₅(C₂F₅)⁻, PF₅(C₃F₇)⁻, PF₄(CF₃)₂⁻, PF₄(CF₃) (C₂F₅)⁻, PF₃(CF₃)₃⁻, B(C₂O₄)₂⁻, CH₃CH₂OSO₃⁻, and CH₃CO₂⁻.

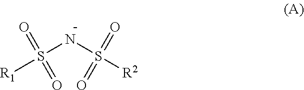

In the formula (A), R¹ and R² each represent a fluorine atom or a perfluoroalkyl group having 1 to 8 carbon atoms, and R¹ and R² may be the same or different from each other.

R¹ and R² each preferably represent a fluorine atom. When R¹ and the R² each represent a fluorine atom, a semiconductor element can be protected from electrostatic breakdown caused by peeling electrification and frictional electrification even under a high-humidity environment and/or under the application of a high voltage.

In the pressure-sensitive adhesive layer-forming composition, the ionic liquid is used in any appropriate amount so that the surface resistivity ρs_{PA} of the pressure-sensitive adhesive layer becomes 1.0×10¹³Ω/□ or less. The content of the ionic liquid in the pressure-sensitive adhesion prevention layer-forming composition is, for example, from 0.1 wt % to 50 wt %, preferably from 0.5 wt % to 30 wt %, more preferably from 1 wt % to 10 wt %. When the content of the ionic liquid falls within the above-mentioned ranges, a semiconductor element can be further protected from electrostatic breakdown caused by peeling electrification and frictional electrification even under a high-humidity environment and/or under the application of a high voltage.

### C-3. Additive

g. The pressure-sensitive adhesive layer-forming composition may contain any appropriate additive. Examples of the additive include a cross-linking agent, a light peeling agent, a catalyst (e.g., a platinum catalyst or a zirconium catalyst), a tackifier, a plasticizer, a pigment, a dye, a filler, an age resistor, a UV absorber, a light stabilizer, a peeling modifier, a softener, a flame retardant, and a solvent.

D. Method of producing Pressure-sensitive Adhesive Sheet for processing Semiconductor Element h. The pressure-sensitive adhesive sheet for processing a semiconductor element may be produced by any appropriate method. The sheet may be obtained by, for example, a method including: applying a pressure-sensitive adhesive solution (pressure-sensitive adhesive layer-forming composition) to the separator; drying the solution to form the pressure-sensitive adhesive layer on the separator; and then bonding the layer to the base material. In addition, the pressure-sensitive adhesive sheet for processing a semiconductor element may be obtained by applying the pressure-sensitive adhesive layer-forming composition onto the base material and drying the composition. Various methods, such as bar coater coating, air knife coating, gravure coating, gravure reverse coating, reverse roll coating, lip coating, die coating, dip coating, offset printing, frexographic printing, and screen printing, may each be adopted as a coating method for the pressure-sensitive adhesive layer-forming composition. Any appropriate method may be adopted as a drying method.

E. Application of Pressure-sensitive Adhesive Sheet for processing Semiconductor Element

i. The pressure-sensitive adhesive sheet for processing a semiconductor element may be suitably used in a process of processing a semiconductor element. In one embodiment, the pressure-sensitive adhesive sheet for processing a semiconductor element according to the embodiment of the present invention may be suitably used as a dicing tape. As described above, the pressure-sensitive adhesive sheet for processing a semiconductor element according to the embodiment of the present invention can suitably protect a semiconductor element even under the application of a high voltage from outside. For example, after a dicing process, the pressure-sensitive adhesive sheet for processing a semiconductor element is peeled from a chuck table. At the time of peeling, a high voltage (e.g., 8,000 V) may be applied to the pressure-sensitive adhesive sheet for processing a semiconductor element. The pressure-sensitive adhesive sheet for processing a semiconductor element according to the embodiment of the present invention can maintain antistatic performance even under the application of a high voltage. As a result, the electrostatic breakdown of the element caused by peeling electrification and frictional electrification that occur in a later pickup process and the like can be prevented.

### EXAMPLES

Now, the present invention is specifically described by way of Examples, but the present invention is not limited to these Examples. In addition, in Examples, “part (s)” and “%” are by weight unless otherwise stated.

### [Production Example 1] Preparation of Base Polymer 1

30 Parts by weight of 2-ethylhexyl acrylate, 70 parts by weight of methyl acrylate, 10 parts by weight of acrylic acid, and 0.2 part by weight of benzoyl peroxide were loaded into a 500-milliliter three-necked flask-type reactor including a temperature gauge, a stirring machine, a nitrogen-introducing tube, and a reflux condenser. Next, the mixture was stirred while a nitrogen gas was introduced for about 1 hour to replace air in the reactor with nitrogen. After that, a temperature therein was set to 60° C., and polymerization was performed by holding the mixture under the state for about 6 hours. Thus, a polymer solution was obtained. The weight-average molecular weight of the polymer measured by gel permeation chromatography (GPC) was 1,200,000.

### Example 1

100 Parts by weight of the base polymer 1, 50 parts by weight of a UV oligomer 1 (manufactured by The Nippon Synthetic Chemical Industry Co., Ltd., product name: SHIKOH UV-1700TL), 45 parts by weight of a UV oligomer 2 (manufactured by The Nippon Synthetic Chemical Industry Co., Ltd., product name: SHIKOH UV-3000TL), 15 parts by weight of a tackifier (manufactured by Yasuhara Chemical Co., Ltd., product name: M-G125), 0.2 part by weight of a light peeling agent (manufactured by TOHO Chemical Industry Co., Ltd., product name: Phosphanol RL-210), 4.5 parts by weight of an ionic liquid (manufactured by DKS Co. Ltd., product name: Elexcel AS-110), 3 parts by weight of a polymerization initiator (manufactured by IGM Resins B.V., product name: Omnirad 2959), 0.05 part by weight of a cross-linking agent 1 (manufactured by Mitsubishi Gas Chemical Company, Inc., product name: TETRAD-C), and 5 parts by weight of a cross-linking agent 2 (manufactured by Nippon Polyurethane Industry Co., Ltd., product name “Coronate L”) were mixed with toluene to provide a pressure-sensitive adhesive layer-forming composition.

Separately, an antistatic layer-forming composition containing 1 part by weight of 2-hydroxyethyltrimethylammonium hydroxide (choline) and 100 parts by weight of a solvent (solvent obtained by mixing water and isopropyl alcohol at 1:1 (weight ratio)) was applied onto both surfaces of a base material (manufactured by Nitto Denko Corporation, product name: Polyethylene (PE) Film, thickness: 150 μm) to form antistatic layers each having a thickness of 100 nm.

The pressure-sensitive adhesive composition was applied onto one surface of the base material having the antistatic layer formed thereon to form a pressure-sensitive adhesive layer having a thickness of 10 μm. Thus, a pressure-sensitive adhesive sheet for processing a semiconductor element was obtained.

### Example 2

A pressure-sensitive adhesive sheet for processing a semiconductor element was obtained in the same manner as in Example 1 except that 1 part by weight of a quaternary ammonium salt (manufactured by Colcoat Co., Ltd., product name: Colcoat NR-121X-9) was used instead of choline in the antistatic layer-forming composition.

### Comparative Example 1

A pressure-sensitive adhesive sheet for processing a semiconductor element was obtained in the same manner as in Example 1 except that 1 part by weight of poly (3,4-ethylenedioxythiophene) doped with poly (4-styrenesulfonic acid) (PEDOT/PSS) (manufactured by Chukyo Yushi Co., Ltd., product name: U-940) was used instead of choline in the antistatic layer-forming composition.

### Comparative Example 2

A commercially available pressure-sensitive adhesive tape (manufactured by InnoX Co., Ltd., product name: IPT-S10PLA-E1) was used.

### <Evaluation 1>

The following evaluations were performed by using the pressure-sensitive adhesive sheets for processing semiconductor elements obtained in Examples and Comparative Examples. The results are shown in Table 1.

### 1. Surface Resistivity

The surface resistivity of each of a base material and a pressure-sensitive adhesive layer was measured in conformity with JIS K 6911. Specifically, a probe was pressed against the surface on the pressure-sensitive adhesive layer side or the surface on the base material side of each of the resultant pressure-sensitive adhesive sheets for processing semiconductor elements, and a stable value after the lapse of 30 seconds from the pressing was read. The measurement was performed under the following measurement conditions.

### <Measurement Conditions>

Resistance meter: HIRESTA MCP-HT450 (manufactured by Mitsubishi Chemical Corporation)
Probe: URS
Temperature: 23° C.+2° C.
Humidity: 50% RH+5% RH

2. Surface Resistivities ρs_{10VBM} and ρs_{10VPA} at Time of Application of 10 V and Surface Resistivities ρs_{1000VBM} and ρs_{1000VPA} at Time of Application of 1,000 V

An application voltage of 10 V or an application voltage of 1,000 V was applied to each of the pressure-sensitive adhesive sheets for processing semiconductor elements obtained in Examples and Comparative Examples for 1 minute with a resistance meter (manufactured by Mitsubishi Chemical Corporation, product name: HIRESTA MCP-HT450). Then, the surface resistivity of each of the base material and the pressure-sensitive adhesive layer was measured in conformity with JIS K 6911. Specifically, a probe was pressed against the surface on the pressure-sensitive adhesive layer side or the surface on the base material side of each of the resultant pressure-sensitive adhesive sheets for processing semiconductor elements, and a stable value after the lapse of 30 seconds from the pressing was read. The measurement was performed under the following measurement conditions.

### <Measurement Conditions>

Resistance meter: HIRESTA MCP-HT450 (manufactured by Mitsubishi Chemical Corporation)
Probe: URS
Temperature: 23° C.+2° C.
Humidity: 50% RH+5% RH

3. Surface Resistivity after Still Standing under High-humidity Environment

Each of the pressure-sensitive adhesive sheets for processing semiconductor elements obtained in Examples and Comparative Examples was left to stand still for 3 days under the conditions of 40° C. and 92% RH. After the still standing, the surface resistivity of each of the base material and the pressure-sensitive adhesive layer was measured in conformity with JIS K 6911. Specifically, a probe was pressed against the surface on the pressure-sensitive adhesive layer side or the surface on the base material side of each of the resultant pressure-sensitive adhesive sheets for processing semiconductor elements, and a stable value after the lapse of 30 seconds from the pressing was read. The measurement was performed under the following measurement conditions.

### <Measurement Conditions>

Resistance meter: HIRESTA MCP-HT450 (manufactured by Mitsubishi Chemical Corporation)
Probe: URS
Temperature: 23° C.+2° C.
Humidity: 50% RH+5% RH

Similarly, each of the pressure-sensitive adhesive sheets for processing semiconductor elements obtained in Examples and Comparative Examples was left to stand still for 3 days under the conditions of 60° C. and 95% RH. After the still standing, the surface resistivity of each of the base material and the pressure-sensitive adhesive layer was measured in conformity with JIS K 6911.

TABLE 1

| | | | | | Comparative | Comparative |
|---|---|---|---|---|---|---|
| | | | Example 1 | Example 2 | Example 1 | Example 2 |
| Pressure- | Polymer | | Base | Base | Base | Commercially |
| sensitive | | | polymer 1 | polymer 1 | polymer 1 | available |
| adhesive | Cross-linking | | Coronate L | Coronate L | Coronate L | pressure- |
| layer | agent | | TETRAD C | TETRAD C | TETRAD C | sensitive |
| | Antistatic | | Ionic | Ionic | Ionic | adhesive |
| | agent of | | liquid | liquid | liquid | tape |
| | pressure- | | | | | |
| | sensitive | | | | | |
| | adhesive | | | | | |
| Base | Antistatic | | Choline | Quaternary | PEDOT/PSS | |
| material | agent of base | | | ammonium | | |
| | material | | | salt | | |
| Surface | Pressure- | Ω/□ | 5.0 × 10¹⁰ | 5.0 × 10¹⁰ | 5.0 × 10¹⁰ | 5.0 × 10¹⁰ |
| resistivity | sensitive | | | | | |
| | adhesive | | | | | |
| | surface | | | | | |
| | Back surface | Ω/□ | 1.0 × 10⁹ | 1.0 × 10¹¹ | 1.0 × 10⁸ | 1.0 × 10⁸ |
| | of base | | | | | |
| | material | | | | | |
| Surface | Pressure- | Ω/□ | 5.0 × 10¹⁰ | 5.0 × 10¹⁰ | 5.0 × 10¹⁰ | 5.0 × 10¹⁰ |
| resistivity | sensitive | | | | | |
| voltage of | adhesive | | | | | |
| 10 V | surface | | | | | |
| | Back surface | Ω/□ | 1.0 × 10⁹ | 1.0 × 10¹¹ | 1.0 × 10⁸ | 1.0 × 10⁸ |
| | of base | | | | | |
| | material | | | | | |
| Surface | Pressure- | Ω/□ | 5.0 × 10¹⁰ | 5.0 × 10¹⁰ | 5.0 × 10¹⁰ | 5.0 × 10¹⁰ |
| resistivity | sensitive | | | | | |
| voltage of | adhesive | | | | | |
| 1,000 V | surface | | | | | |
| | Back surface | Ω/□ | 1.0 × 10⁹ | 1.0 × 10¹¹ | 1.0 × 10¹² | 1.0 × 10¹² |
| | of base | | | | | |
| | material | | | | | |
| Surface | Pressure- | Ω/□ | 5.0 × 10¹⁰ | 5.0 × 10¹⁰ | 5.0 × 10¹⁰ | 5.0 × 10¹⁰ |
| resistivity | sensitive | | | | | |
| 40° C. | adhesive | | | | | |
| 92% | surface | | | | | |
| | Back surface | Ω/□ | 1.0 × 10⁹ | 1.0 × 10¹¹ | 1.0 × 10¹¹ | 1.0 × 10¹¹ |
| | of base | | | | | |
| | material | | | | | |
| Surface | Pressure- | Ω/□ | 5.0 × 10¹⁰ | 5.0 × 10¹⁰ | 5.0 × 10¹⁰ | 5.0 × 10¹⁰ |
| resistivity | sensitive | | | | | |
| 60° C. | adhesive | | | | | |
| 95% | surface | | | | | |
| | Back surface | Ω/□ | 1.0 × 10⁹ | 1.0 × 10¹¹ | over 10¹⁴ | over 10¹⁴ |
| | of base | | | | | |
| | material | | | | | |

<Evaluation 2> Charge Amount after Peeling from Chuck Table

A silicon wafer (manufactured by Shin-Etsu Chemical Co., Ltd.) was bonded to the surface on the pressure-sensitive adhesive layer side of the pressure-sensitive adhesive sheet for processing a semiconductor element of Example 1, and dicing was performed with a dicing device (manufactured by DISCO Corporation). After that, the pressure-sensitive adhesive sheet for processing a semiconductor element was peeled from a chuck table. Then, the charge amount of each of the pressure-sensitive adhesive layer surface and the base material surface of the pressure-sensitive adhesive sheet for processing a semiconductor element was measured for 1 second with a digital low potential measuring device (manufactured by Kasuga Denki, Inc., product name: KSD-0202). The charge amount of the base material surface was 0.0 V, and the charge amount of the pressure-sensitive adhesive layer surface was 0.1 V. Thus, charging was prevented on both of the surfaces.

<Evaluation 3> Charge Amount after Scratching

Evaluation was performed through use of the pressure-sensitive adhesive sheet for processing a semiconductor element of Example 1 and the commercially available pressure-sensitive adhesive tape of Comparative Example 2. Scratching was performed by reciprocating a rubber 10 times on the base material of the pressure-sensitive adhesive sheet subjected to dicing treatment in the same manner as in Evaluation 2. The charge amount of the base material surface of the pressure-sensitive adhesive sheet was measured for 1 second with a digital low product name: KSD-0202) after 0 times, 3 times, 7 times, and 10 times of reciprocation. In the pressure-sensitive adhesive sheet for processing a semiconductor element of Example 1, all the values of the measured charge amounts were 0 V. Meanwhile, in the commercially available pressure-sensitive adhesive tape of Comparative Example 2, the charge amount was 0 V after 0 times of reciprocation, but the charge amount was increased to 200 V, 450 V, and 850 V after 3 times, 7 times, and 10 times of reciprocation, respectively.

### <Evaluation 4> Charge Amount at Time of Pickup

A dicing process was performed in the same manner as in Evaluation 2 through use of the pressure-sensitive adhesive sheet for processing a semiconductor element of Example 1. Then, the pressure-sensitive adhesive sheet for processing a semiconductor element was continuously pushed up with a needle from the base material surface of the pressure-sensitive adhesive sheet so that a wafer cut into small pieces was removed from the pressure-sensitive adhesive sheet. The charge amount of each of the pressure-sensitive adhesive layer side and the base material layer side of a portion, from which the wafer cut into small pieces had been removed, of the pressure-sensitive adhesive sheet for processing a semiconductor element and the charge amount of a wafer adjacent to the removed wafer cut into small pieces were measured for 1 second with a digital low product name: KSD-0202). The charge amount of each of the pressure-sensitive adhesive layer, the base material, and the adjacent layer of the pressure-sensitive adhesive sheet for processing a semiconductor element of Example 1 was 0 V. When the similar measurement was performed through use of a general pressure-sensitive adhesive tape having no antistatic performance (the surface resistivities measured in Evaluation 1 described above were each more than 1.0×10¹⁴Ω/□), the charge amounts of a pressure-sensitive adhesive layer, a base material, and an adjacent layer of the pressure-sensitive adhesive tape were 1,300 V, 1,200 V, and 1,400 V, respectively.

### INDUSTRIAL APPLICABILITY

The pressure-sensitive adhesive sheet for processing a semiconductor element of the present invention may be suitably used for processing a semiconductor element in a semiconductor element-conveying process.

### Reference Character List

10 base material
20 pressure-sensitive adhesive layer
100 pressure-sensitive adhesive sheet for processing a semiconductor element

1. A pressure-sensitive adhesive sheet for processing a semiconductor element, comprising:
a base material; and
a pressure-sensitive adhesive layer,
wherein a surface resistivity PSBM of the base material and a surface resistivity ρs_{PA} of the pressure-sensitive adhesive layer are each 1.0×10¹³Ω/□ or less, and
wherein a surface resistivity ρs_{10VBM} of the base material at a time of application of 10 V and a surface resistivity ρs_{10VPA} of the pressure-sensitive adhesive layer at a time of application of 10 V, and a surface resistivity ρs_{1000VBM} of the base material at a time of application of 1,000 V and a surface resistivity ρs_{1000VPA} of the pressure-sensitive adhesive layer at a time of application of 1,000 V satisfy the following expression (1) and expression (2).
$${ρs}_{1000 VBM} / {ρs}_{10 VBM} \leq 1 , 000 \qquad ( 1 )$$
$${ρs}_{1000 VPA} / {ρs}_{10 VPA} \leq 1 , 000 \qquad ( 2 )$$

2. A pressure-sensitive adhesive sheet for processing a semiconductor element, comprising:
a base material; and
a pressure-sensitive adhesive layer,
wherein a surface resistivity ρs_{BM} of the base material and a surface resistivity ρs_{PA} of the pressure-sensitive adhesive layer are each 1.0×10¹³Ω/□ or less, and
wherein a surface resistivity ρs_{92% BM} of the base material at a humidity of 92% and a surface resistivity ρs_{92% PA} of the pressure-sensitive adhesive layer at a humidity of 92% satisfy the following expression (3) and expression (4).
$${ρs}_{92 \% BM} / {ρs}_{BM} \leq 1 , 000 \qquad ( 3 )$$
$${ρs}_{92 \% PA} / {ρs}_{PA} \leq 1 , 000 \qquad ( 4 )$$

3. The pressure-sensitive adhesive sheet for processing a semiconductor element according to claim 1, wherein the pressure-sensitive adhesive layer contains an ionic liquid.

4. The pressure-sensitive adhesive sheet for processing a semiconductor element according to claim 3, wherein a content of the ionic liquid in a composition for forming the pressure-sensitive adhesive layer is from 0.1 wt % to 50 wt %.

5. The pressure-sensitive adhesive sheet for processing a semiconductor element according to claim 1,
wherein the base material has an antistatic layer on at least one surface thereof, and
wherein the antistatic layer contains a quaternary ammonium salt.

6. The pressure-sensitive adhesive sheet for processing a semiconductor element according to claim 5, wherein a content of the quaternary ammonium salt in a composition for forming the antistatic layer is from 0.1 wt % to 50 wt %.

7. The pressure-sensitive adhesive sheet for processing a semiconductor element according to claim 2, wherein the pressure-sensitive adhesive layer contains an ionic liquid.

8. The pressure-sensitive adhesive sheet for processing a semiconductor element according to claim 7, wherein a content of the ionic liquid in a composition for forming the pressure-sensitive adhesive layer is from 0.1 wt % to 50 wt %.

9. The pressure-sensitive adhesive sheet for processing a semiconductor element according to claim 2,
wherein the base material has an antistatic layer on at least one surface thereof, and
wherein the antistatic layer contains a quaternary ammonium salt.

10. The pressure-sensitive adhesive sheet for processing a semiconductor element according to claim 9, wherein a content of the quaternary ammonium salt in a composition for forming the antistatic layer is from 0.1 wt % to 50 wt %.
